(19) United States
(12) Patent Application Publication
(10) Pub. No.: US 2004/0150075 A1
(43) Pub. Date: Aug. 5, 2004

(54) Semiconductor device with cupper wiring and method for manufacturing semiconductor device

(75) Inventor: Naruhiko Kaji, Kanagawa (JP)

Correspondence Address: LEYDIG VOIT & MAYER, LTD, 700 THIRTEENTH ST. NW, SUITE 300, WASHINGTON, DC, 20005-3960, US

(73) Assignee: Semiconductor Leading Edge Technologies, Inc., Tsukuba-shi (JP)

(21) Appl. No.: 10/735,815

(22) Filed: Dec. 16, 2003

(30) Foreign Application Priority Data
Dec. 16, 2002 (JP) 2002-363396

(51) Int. Cl. H01L 23/58

(52) U.S. Cl. 257/632

(57) ABSTRACT

A porous MSQ is formed on a silicon substrate, and an SiC mask is formed thereon. Plasma etching using the SiC mask as a mask is performed to form a trench in the porous MSQ. A fluorinated polyxylilene film is formed on the entire surface of the substrate 1 including the side surfaces of the trench, and the unnecessary fluorinated polyxylilene film formed on the area other than the side surfaces of the trench is removed. A barrier-metal film and a seed Cu layer are formed in the trench and a Cu is deposited.

1. Field of the Invention

The present invention relates to a wiring structure in a semiconductor device, and particularly to a multi-layer wiring structure using a porous low-k dielectric film as interlayer dielectric film, and a copper wiring.

2. Description of the Background Art

With the miniaturization of semiconductor integrated circuits, the signal delay of metal wirings has become a serious problem.

In order to solve this problem, it has been essential to use copper (Cu) as the wiring material to reduce wiring resistance, and to use a low-k dielectric film as an interlayer dielectric film to reduce interlayer capacitance.

Especially in order to further reduce the interlayer capacitance in next-generation semiconductor integrated circuits, the use of a so-called porous low-k dielectric film (hereafter referred to as “porous low-k film”) having a plurality of pores (voids) in a dielectric film is proposed.

In order to prevent metal diffusion into the porous Low-k film, a method for forming a CVD oxide film on the surface of a trench for wiring has been proposed (e.g., refer to “Japanese Patent Laid-Open No. 9-298241 (Page 5, FIG. 1)”).

The distance between wirings will be further shortened in a next-generation semiconductor integrated circuit with 65 nm nodes. Concurrently, the above-described CVD oxide film formed on the side surfaces of the trench will have a relatively large thickness to the width of the porous low-k film between wirings. In other words, the dielectric constant of the substance formed on the side surfaces of the trench will have a significant effect on the capacitance between lines.

However, since the dielectric constant (k) of the above-described CVD oxide film is about 4.1 to 4.3, there has been a problem that the effective dielectric constant (k_{eff}) of the porous low-k film is increased, and a desired effective dielectric constant cannot be obtained.

### SUMMARY OF THE INVENTION

The present invention has been conceived to solve the previously-mentioned problems and a general object of the present invention is to provide a novel and useful semiconductor device and is to provide a novel and useful method for manufacturing a semiconductor device.

A more specific object of the present invention is to form a multi-layer wiring using a porous low-k dielectric film and a copper wiring while minimizing the increase of the effective dielectric constant of the interlayer dielectric film.

The above object of the present invention is attained by a following semiconductor device and a following method for manufacturing a semiconductor device.

According to one aspect of the present invention, the semiconductor device comprises a porous low-k dielectric film formed on a substrate. An opening portion for wiring is formed in the porous low-k dielectric film. Dielectric films are formed so as to cover only side surfaces of the opening portion, each of the dielectric films having dielectric constant of 3 or less. A wiring is formed in the opening portion.

According to another aspect of the present invention, in the method for manufacturing a semiconductor device, a porous low-k dielectric film is first formed on a substrate. An opening portion for wiring is formed in the porous low-k dielectric film. A dielectric film having a dielectric constant of 3 or less is formed on an entire surface of the substrate including side surfaces of the opening portion. Unnecessary dielectric film formed on the area other than the side surfaces of the opening portion is removed. A conductive film is formed in the opening portion.

Other objects and further features of the present invention will be apparent from the following detailed description when read in conjunction with the accompanying drawings.

### BRIEF DESCRIPTION OF THE DRAWINGS

FIG. 1 is a diagram illustrating a semiconductor device according to an embodiment of the present invention; and

FIGS. 2A to 2D are diagrams illustrating a method for manufacturing a semiconductor device according to the embodiment of the present invention.

### DETAILED DESCRIPTION OF THE PREFERRED EMBODIMENTS

In the following, principles and embodiments of the present invention will be described with reference to the accompanying drawing s. The members and steps that are common to some of the drawings are given the same reference numerals and redundant descriptions therefore may be omitted.

First, a semiconductor device according to an embodiment of the present invention will be described.

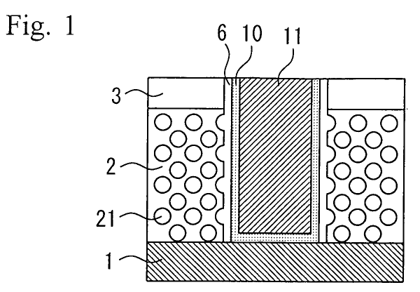

FIG. 1 is a diagram illustrating a semiconductor device according to an embodiment of the present invention.

As FIG. 1 shows, a porous MSQ is formed on a substrate 1 such as a silicon substrate as an ultra-low-k dielectric film (hereafter referred to as “porous low-k film”) 2 having pores (voids) 21. Other than the porous MSQ, the porous low-k film 2 may be, for example, a porous HSQ film, a hybrid film containing both methyl and hydroxyl groups, and a porous organic film containing carbon as the major component. On the porous MSQ (2), an SiC mask is formed as a hard mask 3, and in the porous MSQ (2), a trench 5 is formed as an opening portion for burying wirings. In the following, the case that the trench 5 is formed as the opening portion will be described. The present invention may be applied to the case that a via hole is formed as the opening portion in the porous low-k film. On side surfaces of the trench 5, a dielectric film 6 having a dielectric constant (k) of 3 or less, preferably 2.5 or less is formed. The dielectric film 6 is an organic dielectric film, for example, a fluorinated polyarylene film, such as a fluorinated polyxylylene film, or an amorphous carbon fluoride. In the trench 5, a barrier metal film and a seed Cu layer 10, and Cu film as a metal film 11 are formed.

Next, a method for manufacturing the above-described semiconductor device will be described.

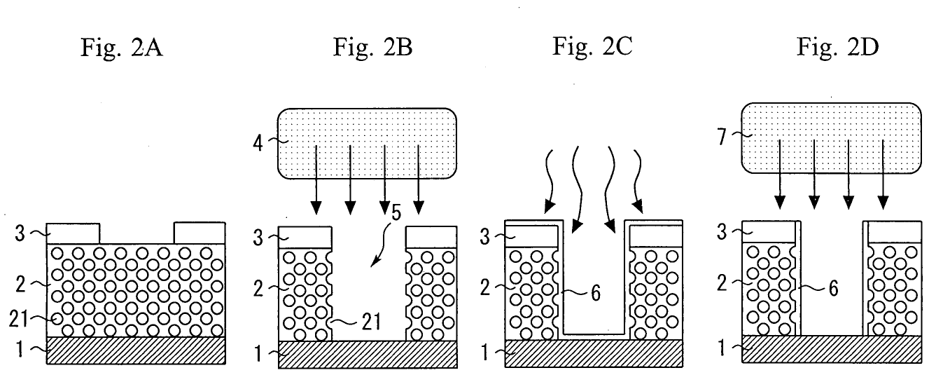

FIGS. 2A to 2D are diagrams illustrating a method for manufacturing a semiconductor device according to the embodiment. Specifically, FIG. 2A is a diagram showing the state after an SiC mask is formed on the porous MSQ; FIG. 2B is a diagram showing the state after a trench is formed in the porous MSQ; FIG. 2C is a diagram showing the state after a low-k dielectric film is formed on the entire surface of the substrate; and FIG. 2D is a diagram showing the state after unnecessary portions of the low-k dielectric film is etched off.

In FIG. 2, the illustration for the formation of the barrier-metal film and the seed layer 10, and the metal (Cu) 11 in FIG. 1 is omitted.

First, as FIG. 2A shows, a porous MSQ (2) having a plurality of pores (voids) 21 is formed on a silicon substrate 1. The size of a pore 21 in the porous MSQ (2) is, for example, several angstroms to several hundred angstroms. Next, an SiC mask 3 is formed on the porous MSQ (2).

Next, as FIG. 2B shows, plasma etching of the porous MSQ (2) is performed using the SiC mask 3 as a mask. Here, in this embodiment, a two-frequency enhanced parallel-plate-type RIE (reactive ion etching) apparatus (not shown) having a lower electrode on which the silicon substrate 1 is placed, and an upper electrode facing to the lower electrode is used as the plasma-etching apparatus.

Specifically, in the plasma etching of the porous MSQ (2), the silicon substrate 1 is first placed on the lower electrode facing the upper electrode. The temperature of the silicon substrate 1 is maintained at about 25° C. using a heat exchanger or the like. Next, as a process gas, C₄F₈/N₂/Ar is introduced into a chamber of the plasma-etching apparatus at the flow rate of 10/225/1400 sccm, respectively, and a pressure in the chamber is maintained at 150 mTorr using an exhaust mechanism. Then, an RF power (high-frequency power) of 1000 W of frequency 60 MHz is applied to the upper electrode, and an RF power of 1400 W of frequency 13.56 MHz is applied to the lower electrode, to generate plasma 4 in the chamber. By anisotropic etching the porous MSQ (2) using the plasma 4, a trench 5 is formed in the porous MSQ (2). After the completion of etching, side surfaces of the trench 5 becomes irregular by the pores (voids) 21 of the porous MSQ (2).

Next, as FIG. 2C shows, a dielectric film having a dielectric constant of 3 or less (hereafter referred to as “low-k dielectric film”) 6 is formed on the entire surface of the silicon substrate 1 including the side surfaces of the trench 5. The case where a fluorinated polyxylylene film (CF₂—C₆H₄—CF₂)ₙ of a dielectric constant of about 2.2 having no voids is formed as the low-k dielectric film 6 will be described below.

First, a fluorine-bonded xylylene compound is heated and gasified in a material container, and the obtained material gas is supplied to a heating reaction mechanism at a flow rate of 5 sccm. In the heating reaction mechanism, the material gas is activated at a temperature of 600° C. to form a precursor. Next, the precursor is introduced to a surface of the silicon substrate 1 maintained at −30° C. (minus 30° C.) on an electrostatic chuck in the chamber maintained at a pressure of about 20 mTorr. Thereby, the polymerization reaction of the precursor occurs on the surface of the silicon substrate 1, and a fluorinated polyxylylene film 6 of a thickness of about 10 nm is formed on the silicon substrate 1. Thereafter, the silicon substrate 1 on which the fluorinated polyxylylene film 6 is formed is transferred to a vertical-type furnace, and undergone a heat treatment at 400° C. for 60 minutes in an N₂ atmosphere of an ambient pressure to stabilize the fluorinated polyxylylene film 6.

Next, as FIG. 2D shows, the unnecessary fluorinated polyxylylene film 6 formed on the area other than the trench 5 is removed using the above-described etching apparatus.

The plasma etching of the fluorinated polyxylylene film 6 will be described. First, the silicon substrate 1 placed on the lower electrode is maintained at about 25° C. using a heat exchanger or the like. Next, as a process gas, N₂/H₂ is introduced into a chamber at the flow rate of 150/250 sccm, respectively, and the pressure in the chamber is maintained at 300 mTorr using an exhaust mechanism. Then, an RF power (high-frequency power) of a frequency of 60 MHz and an output of 1500 W is applied to the upper electrode, and an RF power of a frequency of 13.56 MHz and an RF power of 600 W is applied to the lower electrode, to generate plasma 7 in the chamber. By anisotropic etching the fluorinated polyxylylene film 6 using the plasma 7, the unnecessary fluorinated polyxylylene film 6 is removed leaving the low-k dielectric film 6 only on the side surfaces of the trench 5.

In place of plasma etching using N₂/H₂ gas, sputter etching using Ar gas may be used to remove the unnecessary fluorinated polyxylylene film 6.

As described above, a fluorinated polyxylylene film 6 covering only the side surfaces of the trench 5 formed in the porous MSQ (2) is formed.

Finally, although not shown in the drawing, a conductive film is formed in the trench 5. Specifically, after a barrier metal film and a seed Cu layer (10) are sequentially formed, a metal (11) such as Cu is deposited, and the unnecessary metal is removed by CMP to planarize the metal (11), the seed Cu layer and the barrier metal film (10). Thereby, the semiconductor device as shown in FIG. 1 is obtained.

In this embodiment, as described above, after forming a trench 5 in porous MSQ (2) a fluorinated polyxylylene film 6 is formed on the side surfaces of the trench 5, and thereafter, a conductive film is formed in the trench 5. According to this embodiment, when the conductive film is formed, the pores (voids) 21 of the side surfaces of the trench 5 are covered by the fluorinated polyxylylene film 6, and the irregular shape is improved. Therefore, the conductive film can be formed in the trench 5 at a high coverage and a high adhesiveness.

In this embodiment, the increase of the effective dielectric constant of the interlayer dielectric film 2 was inhibited by covering the side surfaces of the trench 5 with the low-k dielectric film 6 having a dielectric constant of 3 or less. Therefore, while minimizing the increase of the effective dielectric constant, copper can be used for the wiring material to form a multi-layer wiring (Cu/Low-k multi-layer wiring) using a porous low-k film for the interlayer dielectric film. Therefore, the semiconductor device can be miniaturized, and the reliability of the semiconductor device can be improved.

In this embodiment, the side surfaces of the trench 5 are covered with the organic low-k film 6. An inorganic low-k film contains H₂O in it, but the organic low-k film 6 does not contain H₂O in it. Thus, even if the barrier metal film 10 is formed at a poor coverage and Cu (11) is diffused into the organic low-k film 6, diffusion of Cu (11) in the organic low-k film 6 can be restrained comparing to a case that the inorganic low-k film is used for sealing pores. Using the organic low-k film 6 can enlarge process margins.

In this embodiment, although the thickness of the fluorinated polyxylylene film 6 is about 10 nm, the present invention is not limited thereto, but the film thickness can be adequately determined considering the diameter of the trench and hole 5, and the decrease in the quantity of the film when the unnecessary fluorinated polyxylylene film 6 is removed (refer to FIG. 2D).

The use of a film having no pores (voids) as the low-k dielectric film 6 is desired for the purpose of improving the adhesiveness of the conductive film. However, if the diffusion of the conductive material into the porous MSQ (2) can be prevented, the film having pores (voids) and a low void ratio can be applied as the low-k dielectric film 6. In this case, the effect of preventing the increase of the effective dielectric constant is improved comparing to the film having no voids.

When the trench and the hole 5 are formed in separate steps, respectively, the fluorinated polyxylylene films 6 may be simultaneously formed on the side surfaces of the trench and hole after forming them, or the fluorinated polyxylylene films 6 may be formed each time the trench and the hole are formed. From the point of view of productivity the former is preferable.

This invention, when practiced illustratively in the manner described above, provides the following major effects:

According to the present invention, a multi-layer wiring can be formed using a porous low-k dielectric film and a copper wiring, while minimizing the increase of the effective dielectric constant of the interlayer dielectric film.

Further, the present invention is not limited to these embodiments, but variations and modifications may be made without departing from the scope of the present invention.

The entire disclosure of Japanese Patent Application No. 2002-363396 filed on Dec. 16, 2002 containing specification, claims, drawings and summary are incorporated herein by reference in its entirety.

What is claimed is:

1. A semiconductor device comprising:
a porous low-k dielectric film formed on a substrate;
an opening portion for wiring formed in the porous low-k dielectric film;
dielectric films cover only side surfaces of the opening portion, each of the dielectric films having dielectric constant of 3 or less; and
a wiring formed in the opening portion through the dielectric film.

2. The semiconductor device according to claim 1, wherein the dielectric films include a fluorinated polyarylene film or an amorphous carbon fluoride.

3. The semiconductor device according to claim 1, wherein the porous low-k dielectric film includes any one of a porous MSQ, a porous HSQ, a hybrid film containing both methyl and hydroxyl groups, and a porous organic film containing carbon as a major component.

4. A method for manufacturing a semiconductor device comprising the steps of:
forming a porous low-k dielectric film on a substrate;
forming an opening portion for wiring in the porous low-k dielectric film;
forming a dielectric film having a dielectric constant of 3 or less on an entire surface of the substrate including side surfaces of the opening portion;
removing unnecessary dielectric film formed on the area other than the side surfaces of the opening portion; and
forming, after the step of removing unnecessary dielectric film, a conductive film in the opening portion through the dielectric film.

5. The method for manufacturing a semiconductor device according to claim 4, wherein the dielectric film includes a fluorinated polyarylene film or an amorphous carbon fluoride.

6. The method for manufacturing a semiconductor device according to claim 4, wherein the porous low-k dielectric film includes any one of a porous MSQ, a porous HSQ, a hybrid film containing both methyl and hydroxyl groups, and a porous organic film containing carbon as a major component.
